(19) United States
(12) Patent Application Publication
(10) Pub. No.: US 2023/0250530 A1
(43) Pub. Date: Aug. 10, 2023

(54) FILM FORMING APPARATUS AND FILM FORMING METHOD

(71) Applicant: Tokyo Electron Limited, Tokyo (JP)

(72) Inventors: Takamichi KIKUCHI, Nirasaki City, Yamanashi (JP); Jun YAMAWAKU, Nirasaki City, Yamanashi (JP); Tatsuo MATSUDO, Nirasaki City, Yamanashi (JP)

(21) Appl. No.: 18/014,884

(22) PCT Filed: Jun. 30, 2021
(86) PCT No.: PCT/JP2021/024726

§ 371 Date: Jan. 6, 2023

(30) Foreign Application Priority Data
Jul. 10, 2020 (JP) 2020-118965

(51) Int. Cl. C23C 16/455; C23C 16/08; C23C 16/505; C23C 16/44; C23C 16/52

(52) U.S. Cl. CPC C23C 16/45536; C23C 16/08; C23C 16/505; C23C 16/4408; C23C 16/52

(57) ABSTRACT

A film forming method of forming a metallic titanium film on a substrate, includes: a process of forming the metallic titanium film by an atomic layer deposition (plasma enhanced ALD) method that alternately performs an adsorption operation of adsorbing a raw material gas onto a surface of the substrate by supplying the raw material gas into a processing container in which the substrate is accommodated, and a reaction operation of supplying a reactive gas into the processing container to plasmarize the reactive gas and causing the plasmarized reactive gas to react with the raw material gas adsorbed onto the surface of the substrate, wherein, in the reaction operation, the reactive gas is plasmarized with radio frequency power having a frequency of 38 MHz or more and 60 MHz or less.

This is a National Phase application filed under 35 U.S.C. 371 as a national stage of PCT/JP2021/024726, filed Jun. 30, 2021, an application claiming the benefit of Japanese Application No. 2020-118965, filed Jul. 10, 2020, the content of each of which is hereby incorporated by reference in its entirety.

### TECHNICAL FIELD

The present disclosure relates to a film forming apparatus and a film forming method.

### BACKGROUND

Patent Document 1 discloses a method of forming a film on a surface of a substrate.

Patent Document 2 discloses a substrate processing apparatus that performs a film forming processing on a surface of a substrate.

### PRIOR ART DOCUMENT

### Patent Document

Patent Document 1: Japanese laid-open publication No. 2018-059173

Patent Document 2: Japanese laid-open publication No. 2017-155292

### SUMMARY

A technique according to the present disclosure reduces a damage caused in a base of a metallic titanium film when the metallic titanium film is formed by a plasma ALD method.

One aspect of the present disclosure is a film forming method of forming a metallic titanium film on a substrate, which includes: a process of forming the metallic titanium film by an atomic layer deposition (plasma enhanced ALD) method that alternately performs an adsorption operation of adsorbing a raw material gas onto a surface of the substrate by supplying the raw material gas into a processing container in which the substrate is accommodated, and a reaction operation of supplying a reactive gas into the processing container to plasmarize the reactive gas and causing the plasmarized reactive gas to react with the raw material gas adsorbed onto the surface of the substrate, wherein, in the reaction operation, the reactive gas is plasmarized with radio frequency power having a frequency of 38 MHz or more and 60 MHz or less.

According to the present disclosure, it is possible to reduce a damage caused in a base of a metallic titanium film when the metallic titanium film is formed by a plasma ALD method.

### BRIEF DESCRIPTION OF DRAWINGS

FIG. 1 is a longitudinal sectional side view of a film forming apparatus according to the present embodiment.

FIG. 2 is a timing chart of a film forming process in the film forming apparatus of FIG. 1.

FIG. 3 is a diagram illustrating results of SIMS analysis on the rear surface of a Ti film formed by a PEALD method.

FIG. 4 is a diagram illustrating results of SIMS analysis on the rear surface of the Ti film formed by the PEALD method.

### DETAILED DESCRIPTION

In a process of manufacturing a semiconductor device or the like, for example, a film forming process of forming a metallic titanium film (hereinafter sometimes referred to as “Ti film”) on a semiconductor wafer (hereinafter referred to as “wafer”) may be performed. The film forming process of forming the Ti film is performed by a chemical vapor deposition (CVD) method or an atomic layer deposition (ALD) method. Further, as the ALD method, there is known a plasma ALD (plasma enhanced ALD: PEALD) method that alternately and repeatedly performs adsorbing a raw material gas onto a surface of the wafer, and subsequently causing the raw material gas adsorbed onto the surface of the wafer W to react with a reactive gas in the form of a plasma (see Patent Documents 1 and 2).

In the CVD method, when a film is not formed at a relatively high temperature, a concentration of impurities in the film may increase. Meanwhile, in the PEALD method, a film may be formed with a low concentration of impurities even at a relatively low temperature. For this reason, it may be considered that the PEALD method is employed to form the Ti film. However, the PEALD method may reduce a damage caused in a base of the Ti film when the Ti film is formed by the PEALD method.

Therefore, a technique according to the present disclosure reduces a damage caused in a base of a metallic titanium film when the metallic titanium film is formed by a plasma ALD method.

Hereinafter, a film forming method and a film forming apparatus according to the present embodiment will be described with reference to drawings. In addition, in this specification and the accompanying drawings, elements having substantially the same functional configurations will be denoted by the same reference numerals, and redundant explanations thereof will be omitted.

### [Film Forming Apparatus]

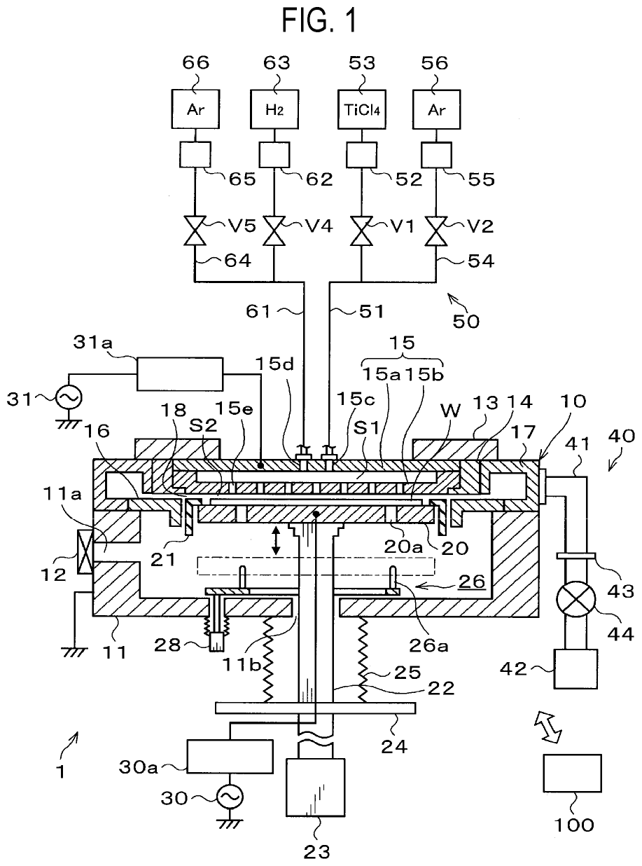

FIG. 1 is a longitudinal sectional side view schematically illustrating a film forming apparatus according to the present embodiment.

A film forming apparatus 1 illustrated in FIG. 1 is a single wafer type apparatus. Further, the film forming apparatus 1 forms a Ti film on the wafer W serving as a substrate. Specifically, the film forming apparatus 1 forms the Ti film by the PEALD method. In the PEALD method, an adsorption operation and a reaction operation, which are described later, are alternately performed. In the adsorption operation, a raw material gas is supplied into a processing container 10 to be described later in which the wafer W is accommodated, so that the raw material gas is adsorbed onto the surface of the wafer W. In the reaction operation, a reactive gas is supplied into the processing container 10 where the reactive gas is plasmarized, and the raw material gas adsorbed onto the surface of the wafer W reacts with the plasmarized reactive gas.

The film forming apparatus 1 includes the processing container 10 which is configured to be capable of being depressurized and accommodates the wafer W therein.

The processing container 10 has a container main body 11 formed in a bottomed cylindrical shape.

A sidewall of the container main body 11 is provided with an opening 11a which is a loading/unloading port for the wafer W and a gate valve 12 which opens and closes the opening 11a. Further, an exhaust duct 17 (to be described later), which constitutes a portion of the sidewall of the processing container 10, is provided on the container main body 11.

Further, a stage 20 on which the wafer W is placed is provided inside the processing container 10. The stage 20 constitutes a lower electrode. A heater (not illustrated) as a heating mechanism which heats the wafer W is built in the stage 20. Thus, the wafer W placed on the stage 20 may be heated to a predetermined temperature.

Radio frequency power for bias is supplied to the stage 20 from a radio frequency power supply 30 provided outside the processing container 10 via a matcher 30a.

Alternatively, the radio frequency power supply 30 may be omitted, and no radio frequency power for bias may be supplied to the stage 20.

Further, a cylindrical cover member 21 is provided in the stage 20 so as to surround the stage 20. An upper end of a post 22 extending in a vertical direction is connected to a central portion of a lower surface of the cover member 21. A lower end of the post 22 extends outward of the processing container 10 through an opening 11b provided in a bottom of the processing container 10, and is connected to a lifting mechanism 23. The stage 20 is capable of vertically moving between a transfer position indicated by the one-dot dashed line and a processing position above the transfer position with a driving operation of the lifting mechanism 23. The transfer position is a position where the stage 20 stands by when transferring the wafer W between a transfer mechanism (not illustrated) for the wafer W which enters the processing container 10 from the opening 11a of the processing container 10 and support pins 26a to be described later. Further, the processing position is a position where the wafer W is processed.

A flange 24 is provided around the post 22 outside the processing container 10. A bellows 25 is provided between the flange 24 and a portion of the post 22 penetrating a bottom wall of the processing container 10 so as to surround an outer periphery of the post 22. Thus, the processing container 10 is maintained in an air-tight state.

A wafer lifting member 26 including a plurality of, for example, three support pins 26a, is provided below the stage 20 inside the processing container 10. The wafer lifting member 26 is vertically movable by a lifting mechanism 28. Further, with such a vertical movement, the support pins 26a move upward and downward with respect to an upper surface of that stage 20 through respective through-holes 20a formed in the stage 20 to deliver the wafer W.

An annular insulating support member 13 is provided on a top of the exhaust duct 17 in the processing container 10. A shower head support member 14 made of quartz is provided on a lower surface of the insulating support member 13. A shower head 15, which is a gas introducer for introducing a processing gas into the processing container 10 and constitutes an upper electrode, is supported by the shower head support member 14.

The shower head 15 includes a head main body portion 15a having a disk shape and a shower plate 15b connected to the head main body portion 15a. A gas diffusion space S1 is defined between the head main body portion 15a and the shower plate 15b. The head main body portion 15a and the shower plate 15b are made of a metal. Two gas supply paths 15c and 15d are formed in the head main body portion 15a to communicate with the gas diffusion space S1. A large number of gas discharge holes 15e are formed in the shower plate 15b to communicate with the gas diffusion space S1.

Further, radio frequency power for plasma generation is supplied to the shower head 15 from a radio frequency power supply 30 provided outside the processing container 10 via a matcher 31a.

Further, an annular member 16 is provided inside the processing container 10 and is formed such that an inner wall of the processing container 10 protrudes above the opening 11a. The annular member 16 is disposed so as to surround the cover member 21 of the stage 20 at the processing position in close to the outer side of the cover member 21. Further, the exhaust duct 17, which is formed to be curved in an annular shape, is provided at an upper portion of the sidewall of the processing container 10. An inner peripheral surface side of the exhaust duct 17 is open over the annular member 16 in the circumferential direction. The exhaust duct 17 is capable of exhausting a processing space S2 through a gap 18 formed between the cover member 21 and a lower peripheral edge portion of the shower plate 15b.

An exhaust mechanism 40 is connected to the exhaust duct 17 to exhaust the interior of the processing container 10. The exhaust mechanism 40 includes an exhaust pipe 41 and a vacuum exhaust pump 42. One end of the exhaust pipe 41 is connected to the exhaust duct 17, and the other end of the exhaust pipe 41 is connected to the vacuum exhaust pump 42. An APC valve 43 and an on-off valve 44 are provided in order from the upstream side between the exhaust duct 17 and the vacuum exhaust pump 42 in the exhaust pipe 41.

Further, the above-described gas supply paths 15c and 15d are connected to a gas supply mechanism 50 which supplies the raw material gas and the reactive gas to the processing container 10. Specifically, the gas supply paths 15c and 15d are connected to downstream ends of gas flow paths 51 and 61 of the gas supply mechanism 50, respectively.

An upstream end of the gas flow path 51, which serves as a raw material gas flow path, is connected to a source 53 of a TiCl₄ gas which is the raw material gas, via a valve V1 and a flow rate adjustor 52 which are provided in this order from the downstream side.

The flow rate adjustor 52 is configured with a mass flow controller and adjusts a flow rate of the TiCl₄ gas supplied from the source 53 to the downstream side. In addition, each of other flow rate adjustors 55, 62 and 65 to be described later is similar in configuration to the flow rate adjustor 52, and adjusts a flow rate of gas supplied to the downstream side of the respective flow path.

The valve V1 is opened or closed to supply or cutoff the TiCl₄ gas from the source 53 to the processing container 10. V2, V4 and V5 to be described later are also opened or closed to supply or cutoff gases from sources 56, 63 and 66 to the processing container 10, respectively.

Further, a downstream end of a gas flow path 54 is connected to the downstream side of the valve V1 in the gas flow path 51. An upstream end of the gas flow path 54 is connected to the source 56 of an Ar gas via the valve V2 and the flow rate adjustor 55 which are provided in this order from the downstream side. The Ar gas from the source 56 is supplied into the processing container 10 to dilute the TiCl₄ gas which is the raw material gas.

Next, the gas flow path 61 connected to the gas supply path 15d of the processing container 10 will be described.

An upstream end of the gas flow path 61, which serves as a reactive gas flow path, is connected to the source 63 of an H₂ gas, which is the reactive gas, via the valve V4 and the flow rate adjustor 62 which are provided in this order from the downstream side.

A downstream end of a gas flow path 64 is connected to the downstream side of the valve valve V4 in the gas flow path 61. An upstream end of the gas flow path 64 is connected to the source 66 of an Ar gas via the valve V5 and the flow rate adjustor 65 which are provided in this order from the downstream side. The Ar gas from the source 66 is supplied into the processing container 10 to form plasma.

The film forming apparatus 1 configured as above is provided with a controller 100. The controller 100 is configured with a computer including, for example, a CPU, a memory, and the like, and is provided with a program storage (not illustrated). The program storage stores programs or the like for controlling respective devices such as the heater (not illustrated) in the stage 20, the gate valve 12, the valves V1, V2, V4 and V5, the APC valve 43, and the flow rate adjustors 52, 55, 62 and 65 to implement a wafer processing to be described later in the film forming apparatus 1. Further, the programs are recorded on a computer-readable storage medium and may be installed from the storage medium to the controller 100. The storage medium may be transitory or non-transitory. Further, a portion or all of the programs may be implemented by dedicated hardware (circuit board).

### <Film Forming Method>

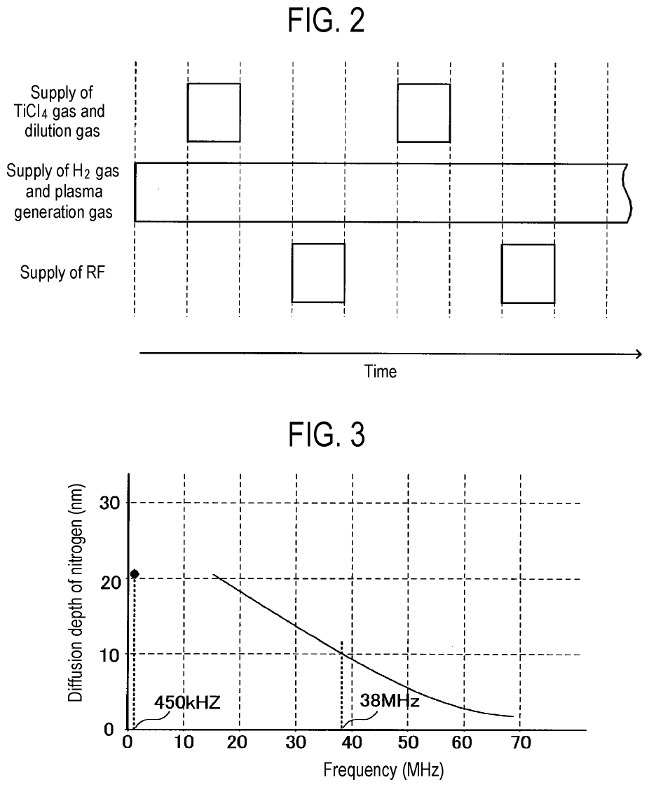

Next, the wafer processing in the film forming apparatus 1 will be described with reference to FIG. 2. FIG. 2 is a timing chart of the wafer processing in the film forming apparatus 1.

### (Step S1: Wafer Loading)

First, the gate valve 12 is opened with the valves V1, V2, V4 and V5 closed. Subsequently, the transfer mechanism (not illustrated), which holds the wafer W, is inserted into the processing container 10, which is evacuated in advance by the exhaust mechanism 40, from a transfer chamber (not illustrated) which is kept in a vacuum atmosphere and adjacent to that processing container 10, through the opening 11a. Subsequently, the wafer W is transferred above the stage 20 located at the above-described transfer position. Then, the wafer W is delivered onto the raised support pins 26a. Thereafter, the transfer mechanism is taken out from the processing container 10, and the gate valve 12 is closed. At the same time, the support pins 26a are lowered, and the wafer W is placed on the stage 20. In addition, the stage 20 is controlled in advance to have a predetermined film forming temperature, for example, 300 degree C. to 450 degree C. by the heater (not illustrated) embedded therein. After the wafer W is placed on the stage 20, the stage 20 is moved to the above-described processing position, the processing space S2 is formed, and an internal pressure of the processing container 10 is controlled to a desired vacuum pressure by the APC valve 43.

### (Step S2: Start of Supply of Base Gas)

Then, the valves V4 and V5 are opened, and the H₂ gas as a reactive gas and the Ar gas as a plasma generation gas are supplied from the source 63 and from the source 66 to the processing container 10 through the gas flow path 61 and the gas flow path 64, respectively. The H₂ gas as the reactive gas and the Ar gas as the plasma generation gas are allowed to flow constantly during film formation. A flow rate of the H₂ gas as the reactive gas is, for example, 3,500 sccm to 7,000 sccm, and a flow rate of the Ar gas as the plasma generation gas is, for example, 300 sccm to 3,500 sccm. Further, during the film forming process including operations of steps S3 to S6 to be described later, the internal pressure of the processing container 10 is adjusted to a desired vacuum pressure, for example, 500 mTorr or more and 5 Torr or less by the APC valve 43.

### (Step S3: Adsorption)

After a preset period of time has elapsed from the start of the supply of the reactive gas and the plasma generation gas, the valves V1 and V2 are opened. Thus, the TiCl₄ gas as the raw material gas and the Ar gas as the dilution gas are supplied from the source 53 and from the source 56 to the processing container 10 through the gas flow path 51 and the gas flow path 54, respectively. In addition, a flow rate of the TiCl₄ gas as the raw material gas is, for example, 5 sccm to 15 sccm, and a flow rate of the Ar gas as the dilution gas is, for example, 300 sccm to 3,500 sccm. This adsorption operation is performed for 0.05 seconds to 0.1 seconds, for example.

### (Step S4: Discharge of Raw Material Gas or the Like)

After completion of the adsorption operation, the valves V1 and V2 are closed, the supply of the TiCl₄ gas and the Ar gas as the dilution gas is stopped, and the supply of the H₂ gas as the reactive gas and the Ar gas for plasma generation is continued. The TiCl₄ gas and the like are discharged (purged) from the interior of the processing container 10 by the H₂ gas and the Ar gas for plasma generation. As described above, the H₂ gas as the reactive gas and the Ar gas for plasma generation are also used as a purge gas. In addition, the operation of discharging the raw material gas and the like is performed for 0.4 seconds to 1 second, for example.

### (Step S5: Reaction)

After a preset period of time has elapsed from the closing of the valves V1 and V2, the radio frequency power for bias is supplied from the radio frequency power supply 30 and the radio frequency power for plasma generation is supplied from the radio frequency power supply 31. Thus, the H₂ gas as the reactive gas and the Ar gas for plasma generation in the processing container 10 are plasmarized so that the plasmarized reactive gas reacts with the TiCl₄ gas. Specifically, TiCl₄ adsorbed to the wafer W is reduced to metallic titanium by active species such as H₃⁺ ions produced by such a plasmarization. In this reaction operation, a frequency of the radio frequency power for plasma generation supplied from the radio frequency power supply 31 is 38 MHz or more and 60 MHz or less. In addition, the reaction operation is performed for 1 second to 4 seconds, for example.

### (Step S6: Discharge of Active Species)

After completion of the reaction operation, the supply of the radio frequency power for bias from the radio frequency power supply 30 and the supply of the radio frequency power for plasma generation from the radio frequency power supply 31 are stopped, and the supply of the H₂ gas as the reactive gas and the Ar gas for plasma generation is continued. The active species and the like remaining in the processing container 10 are discharged by the H₂ gas and the Ar gas for plasma generation. The operation of discharging the active species is performed for 0.3 seconds to 1 second, for example.

One cycle including steps S3 to S6 described above is repeatedly performed so that an atomic layer of Ti is deposited on the surface of the wafer W to form a Ti film.

### (Step S7: Unloading)

Then, when the above cycle is performed a predetermined number of times and a Ti film having a desired film thickness is formed, the wafer W is unloaded from the processing container 10 in a reverse order to that of being loaded into the processing container 10. In this way, a series of wafer processing is completed.

As described above, the film forming method according to the present embodiment includes the operation of forming the Ti film by the PEALD method that alternately performs the above-described adsorption operation and reaction operation. Also in the reaction operation, the reactive gas is plasmarized with the radio frequency power having a frequency of 38 MHz or more and 60 MHz or less.

In the present embodiment, since the frequency of the radio frequency power for plasmarizing the reactive gas, that is, the radio frequency power for plasma generation, is 38 MHz or more, as will be described later, it is possible to greatly reduce a damage caused in a base of the Ti film when the Ti film is formed by the PEALD method.

Further, in the present embodiment, the following effects are obtained since the frequency of the radio frequency power for plasma generation is 60 MHz or less. That is, since an impedance of a radio frequency power supply circuit for bias including the stage 20 as the lower electrode may not be sufficiently lowered, the higher the frequency of the radio frequency power for plasma generation, the larger the percentage of generated plasma directed toward the sidewall of the container main body 11, which deteriorates a density of plasma near the stage 20. On the other hand, in the present embodiment, since the frequency of the radio frequency power for plasma generation is 60 MHz or less, the percentage of generated plasma directed toward the sidewall of the container main body 11 is small, and the plasma density near the stage 20 is sufficiently high. Therefore, the film forming efficiency of the Ti film is not deteriorated.

That is, in the present embodiment, since the frequency of the radio frequency power for plasma generation is 38 MHz or more and 60 MHz or less, it is possible to prevent the damage caused in the base of the Ti film when the Ti film is formed by the PEALD method without impairing productivity.

Further, as a result of the earnest research conducted by the present inventors, it was found that, since the frequency of the radio frequency power for plasma generation is 38 MHz or more, it is possible to reduce a surface roughness of the Ti film compared to when the frequency is less than 38 MHz. Further, it was found that it is possible to further reduce the surface roughness of the Ti film by lowering an output of the radio frequency power for plasma generation while setting the frequency of the radio frequency power for plasma generation to 38 MHz or more.

In addition, as described above, the reason why the damage caused in the base of the Ti film may be greatly reduced by setting the frequency of the radio frequency power for plasma generation to 38 MHz or more may be contemplated as follows. That is, by increasing the frequency of the radio frequency power for plasma generation, (A) the density of H radicals in the plasma increases and the density of H₃⁺ ions relatively decreases, and (B) the energy of H₃⁺ ions decreases. As a result, it is contemplated that this is because the amount and depth of H₃⁺ ions implanted into the base of the Ti film are reduced, making it difficult for nitrogen, oxygen, or the like to be introduced.

### Experimental Example

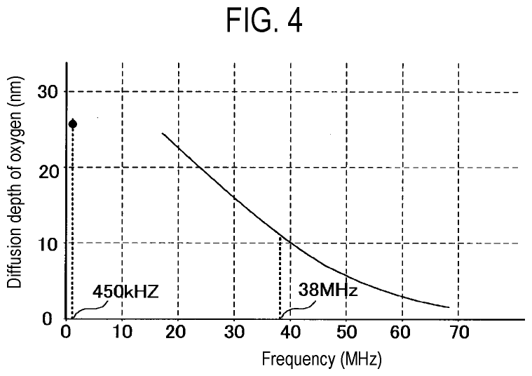

A Ti film was formed on a Si wafer W by the PEALD method in the same manner as described above while changing the frequency of the radio frequency power for plasma generation, and rear surface secondary ion mass spectrometry (SIMS) analysis was performed. The results are shown in FIGS. 3 and 4. In FIGS. 3 and 4, the horizontal axis represents the frequency. Further, the vertical axis of FIG. 3 represents the thickness of a portion of the Si wafer W having the Ti film formed thereon where the concentration of nitrogen is 10²⁰ atms/cm³ or more (hereinafter referred to as a diffusion depth of nitrogen). The vertical axis of FIG. 4 represents the thickness of a portion of the same wafer W where the concentration of oxygen is 10²⁰ atms/cm³ or more (hereinafter referred to as a diffusion depth of oxygen). In addition, the output of the radio frequency power for plasma generation was made common when the Ti film was formed at each frequency.

As illustrated in FIG. 3, when the Ti film was formed on the Si wafer W by the PEALD method, the diffusion depth of nitrogen decreased as the frequency of the radio frequency power for plasma generation increased. And when the frequency of the radio frequency power for plasma generation is 38 MHz or more, the diffusion depth of nitrogen was ½ or less of that when the frequency is 450 kHz.

Further, as illustrated in FIG. 4, when the Ti film was formed on the Si wafer W by the PEALD method, the diffusion depth of oxygen decreased as the frequency of the radio frequency power for plasma generation increased. And when the frequency of the radio frequency power for plasma generation is 38 MHz or more, the diffusion depth of oxygen was ½ or less of that when the frequency is 450 kHz.

From the results illustrated in FIGS. 3 and 4, it can be seen that, when the Ti film was formed on the Si wafer W by the PEALD method, the diffusion degree of nitrogen or oxygen in the depth (thickness) direction may be reduced by increasing the frequency of the radio frequency power for plasma generation. In particular, it can be seen that the above diffusion degree may be greatly reduced when the frequency of the radio frequency power for plasma generation is set to 38 MHz or more. That is, by setting the frequency of the radio frequency power for plasma generation to 38 MHz or more, it is possible to greatly reduce a damage to the Si wafer W as a base when the Ti film is formed by the PEALD method.

### Other Applications

The embodiments disclosed herein should be considered to be exemplary and not limitative in all respects. The above embodiments may be omitted, replaced or modified in various embodiments without departing from the scope of the appended claims and their gist.

### EXPLANATION OF REFERENCE NUMERALS

1: Film forming apparatus
11: Container main body
31: Radio frequency power supply
100: Controller
W: Wafer

1-6: (canceled)

7. A film forming method of forming a metallic titanium film on a substrate, the film forming method comprising:
a process of forming the metallic titanium film by an atomic layer deposition method that alternately performs an adsorption operation of adsorbing a raw material gas onto a surface of the substrate by supplying the raw material gas into a processing container in which the substrate is accommodated, and a reaction operation of supplying a reactive gas into the processing container to plasmarize the reactive gas and causing the plasmarized reactive gas to react with the raw material gas adsorbed onto the surface of the substrate,
wherein, in the reaction operation, the reactive gas is plasmarized with radio frequency power having a frequency of 38 MHz or more and 60 MHz or less.

8. The method of claim 7, wherein the raw material gas contains TiCl₄, and the reactive gas contains H₂.

9. The method of claim 8, wherein an internal pressure of the processing container in the process of forming the metallic titanium film is 500 mTorr or more and 5 Torr or less.

10. The method of claim 7, wherein an internal pressure of the processing container in the process of forming the metallic titanium film is 500 mTorr or more and 5 Torr or less.

11. A film forming apparatus that forms a metallic titanium film on a substrate, comprising:
a processing container in which the substrate is accommodated;
a gas supply mechanism configured to supply a raw material gas and a reactive gas into the processing container;
a radio frequency power supply configured to output radio frequency power for generating plasma inside the processing container; and
a controller,
wherein the controller controls the gas supply mechanism and the radio frequency power supply so that a process of forming the metallic titanium film is performed by an atomic layer deposition method that alternately performs an adsorption operation of adsorbing the raw material gas onto a surface of the substrate by supplying the raw material gas into the processing container in which the substrate is accommodated, and a reaction operation of supplying the reactive gas into the processing container to plasmarize the reactive gas and causing the plasmarized reactive gas to react with the raw material gas adsorbed onto the surface of the substrate, and
wherein in the reaction operation, the reactive gas is plasmarized with the radio frequency power having a frequency of 38 MHz or more and 60 MHz or less.

12. The film forming apparatus of claim 11, wherein the gas supply mechanism supplies TiCl₄ as the raw material gas and supplies H₂ as the reactive gas.

13. The film forming apparatus of claim 12, further comprising an exhaust mechanism configured to exhaust an interior of the processing container,
wherein the controller controls the gas supply mechanism and the exhaust mechanism so that an internal pressure of the processing container in the process of forming the metallic titanium film becomes 500 mTorr or more and 5 Torr or less.

14. The film forming apparatus of claim 11, further comprising an exhaust mechanism configured to exhaust an interior of the processing container,
wherein the controller controls the gas supply mechanism and the exhaust mechanism so that an internal pressure of the processing container in the process of forming the metallic titanium film becomes 500 mTorr or more and 5 Torr or less.
